(19) United States
(12) Patent Application Publication
(10) Pub. No.: US 2026/0117365 A1
(43) Pub. Date: Apr. 30, 2026

(54) EVAPORATOR DESIGN WITH LOW HEAT LOADS

(71) Applicant: Applied Materials, Inc., Santa Clara, CA (US)

(72) Inventors: Sambhu Kundu, Santa Clara, CA (US); Prasanna Kalleshwara Buddappa Ramachandrappa, Santa Clara, CA (US); Visweswaren Sivaramakrishnan, Santa Clara, CA (US); Sandip Sambhajirao Desai, Bangalore (IN); Sumedh Dattatraya Acharya, Bangalore (IN); Subramanya P Herle, Santa Clara, CA (US)

(21) Appl. No.: 19/123,658

(22) PCT Filed: Oct. 12, 2023
(86) PCT No.: PCT/US2023/035041

§ 371 Date: Apr. 23, 2025

Related U.S. Application Data
(60) Provisional application No. 63/418,905, filed on Oct. 24, 2022.

(51) Int. Cl. C23C 14/24; C23C 14/26

(52) U.S. Cl. CPC C23C 14/243; C23C 14/26

(57) ABSTRACT

A method and apparatus for thermal evaporation are provided. The thermal evaporator includes an evaporator body operable for both holding and evaporating a coating material to be deposited. The evaporator body includes a cylindrical wall having a first end and a second end opposite the first end, a first sidewall perpendicular to and coupled with the first end of the cylindrical wall, and a second sidewall perpendicular to and coupled with the second end of the cylindrical wall. The evaporator body defines an interior region. The interior region has a source region operable for holding and evaporating the coating material to be deposited and an evaporation region, which is operable for heating to maintain the evaporated coating material to be deposited in vapor phase. The thermal evaporator further includes heating sources positioned in both the source region and the evaporation region.

### TECHNICAL FIELD

The present disclosure generally relates to an evaporation system for providing a gas for a reactive deposition process. More particularly, the present disclosure generally relates to a thermal evaporator design, which provides a uniform evaporation rate at relatively low temperatures.

### BACKGROUND

Processing of flexible substrates, such as plastic films or foils, is in high demand in the packaging industry, semiconductor industry, and other industries. Processing can include coating of a flexible substrate with a chosen material, such as a metal. The economical production of these coatings is limited by the thickness uniformity necessary for the product, the reactivity of the coating materials, the cost of the coating materials, and the deposition rate of the coating materials. The most demanding applications generally involve deposition in a vacuum chamber for precise control of the coating thickness and the optimum optical properties. The high capital cost of vacuum coating equipment necessitates a high throughput of coated area for large-scale commercial applications. The coated area per unit time is typically proportional to the coated substrate width and the vacuum deposition rate of the coating material.

A deposition process that can utilize a large vacuum chamber has tremendous economic advantages. Vacuum coating chambers, substrate treating and handling equipment, and pumping capacity, increase in cost less than linearly with chamber size. Therefore, the most economical process for a fixed deposition rate and coating design will utilize the largest substrate available. A larger substrate can generally be fabricated into discrete parts after the coating process is complete. In the case of products manufactured from a continuous web, the web is slit or sheet cut to either a final product dimension or a narrower web suitable for the subsequent manufacturing operations.

One technique used for deposition is thermal evaporation. Thermal evaporation takes place when a source material is heated in an open crucible within a vacuum chamber when a temperature is reached such that there is a sufficient vapor flux from the source for condensation on a cooler substrate. The source material can be heated indirectly by heating the crucible, or directly by a high current electron beam directed into the source material confined by the crucible. Thermal evaporation typically takes place at high temperatures, which can lead to high thermal loads on the substrate being processed. These high thermal loads can damage the substrate. One method for reducing thermal load includes cooling the crucible through radiative cooling. However, radiative cooling is typically very slow, which can lead to significant chamber downtime and an increase in cost of ownership.

In addition, current thermal evaporator designs, which use external heaters can suffer from radiative heat loss, which can lead to increased power consumption to achieve targeted temperatures.

Thus, there is a need for apparatus and methods for reducing the thermal load on substrates during thermal evaporation processes.

### SUMMARY

The present disclosure generally relates to an evaporation system for providing a gas for a reactive deposition process. More particularly, the present disclosure generally relates to a thermal evaporator design, which provides a uniform evaporation rate at relatively low temperatures.

In one aspect, a thermal evaporator is provided. The thermal evaporated includes an evaporator body operable for holding and evaporating a coating material to be deposited. The evaporator body includes a cylindrical wall having a first end and a second end opposite the first end. The evaporator body further includes a first sidewall perpendicular to and coupled with the first end of the cylindrical wall and a second sidewall perpendicular to and coupled with the second end of the cylindrical wall. The cylindrical wall, the first sidewall, and the second sidewall define an interior region. The interior region has a source region operable for holding and evaporating the coating material to be deposited and an evaporation region, which is operable for heating to maintain the evaporated coating material to be deposited in vapor phase. The thermal evaporator further includes one or more first heating sources positioned in the source region. The one or more first heating sources extend along a first direction from the first sidewall to the second sidewall. The thermal evaporator further includes one or more second heating sources positioned in the evaporation region. The one or more second heating sources extend along the first direction from the first sidewall to the second sidewall. The thermal evaporator further includes a linear array of nozzles fluidly coupled with the interior region via the cylindrical wall and operable to deliver the evaporated coating material.

Implementations may include one or more of the following features. The thermal evaporator where the evaporator body may include a material selected from molybdenum, graphite, stainless steel, boron nitride, or a combination thereof. The evaporator body is machined from a single piece of the material. At least one of the one or more first heating sources and the one or more second heating sources may include a heating rod. The heating rod is positioned in a tube that extends along the first direction from the first end of the cylindrical wall to the second end of the cylindrical wall; the tube may include a thermally conductive material. The one or more second heating sources are conductively coupled with the evaporator body via a source mount. The source mount may include the same material as the evaporator body. The one or more second heating sources are positioned adjacent to the linear array of nozzles. The linear array of nozzles extends along the first direction from the first sidewall to the second sidewall. At least one of the one or more first heating sources and the one or more second heating sources may include a material selected from graphite, aluminum oxide, aluminum nitride, boron nitride, and titanium diboride.

In another aspect, a system for coating a substrate by evaporating a coating material in a vacuum chamber is provided. The system includes a thermal evaporator. The thermal evaporator includes an evaporator body operable for holding and evaporating a coating material to be deposited. The evaporator body includes a cylindrical wall having a first end and a second end opposite the first end. The evaporator body further includes a first sidewall perpendicular to and coupled with the first end of the cylindrical wall. The evaporator body further includes a second sidewall perpendicular to and coupled with the second end of the cylindrical wall. The cylindrical wall, the first sidewall, and the second sidewall define an interior region. The interior region has a source region operable for holding and evaporating the coating material to be deposited and an evaporation region, which is operable for heating to maintain the evaporated coating material to be deposited in vapor phase. The thermal evaporator further includes one or more first heating sources positioned in the source region. The one or more first heating sources extend along a first direction from the first sidewall to the second sidewall. The thermal evaporator includes one or more second heating sources positioned in the evaporation region. The one or more second heating sources extend along the first direction from the first sidewall to the second sidewall. The thermal evaporator further includes a linear array of nozzles fluidly coupled with the interior region via the cylindrical wall and operable to deliver the evaporated coating material. The system further includes at least one containment shield disposed about the thermal evaporator, the containment shield defining a deposition zone for confinement of the evaporated coating material to be deposited. The system further includes a coating drum for supporting a continuous flexible substrate to be coated in the deposition zone. The system further includes a vacuum chamber, where the thermal evaporator, the at least one containment shield, and the coating drum are disposed therein.

Implementations may include one or more of the following features. The system where the evaporator body may include a material selected from molybdenum, graphite, stainless steel, boron nitride, or a combination thereof. The evaporator body is machined from a single piece of the material. At least one of the one or more first heating sources and the one or more second heating sources may include a heating rod. The heating rod is positioned in a tube that extends along the first direction from the first end of the cylindrical wall to the second end of the cylindrical wall; the tube may include a thermally conductive material. The one or more second heating sources are conductively coupled with the evaporator body via a source mount. The source mount may include the same material as the evaporator body. The one or more second heating sources are positioned adjacent to the linear array of nozzles. The linear array of nozzles extends along the first direction from the first sidewall to the second sidewall. At least one of the one or more first heating sources and the one or more second heating sources may include a material selected from graphite, aluminum oxide, aluminum nitride, boron nitride, and titanium diboride. The system may include a power supply coupled to at least one of the one or more first heating sources and the one or more second heating sources and providing an electrical current therethrough for heating the at least one of the one or more first heating sources and the one or more second heating sources.

In yet another aspect, a method of evaporating a coating material for coating a continuous flexible substrate if provided. The method includes supplying a quantity of a coating material to be evaporated into a source region of a thermal evaporator. The thermal evaporator includes an evaporator body operable for holding and evaporating the coating material to be deposited. The evaporator body includes a cylindrical wall having a first end and a second end opposite the first end; a first sidewall perpendicular to and coupled with the first end of the cylindrical wall; a second sidewall perpendicular to and coupled with the second end of the cylindrical wall. The cylindrical wall, the first sidewall, and the second sidewall define an interior region. The interior region has the source region operable for holding and evaporating the coating material to be deposited and an evaporation region, which is heated to maintain the evaporated coating material to be deposited in vapor phase. The thermal evaporator further includes one or more first heating sources positioned in the source region, where the one or more first heating sources extend along a first direction from the first sidewall to the second sidewall; one or more second heating sources positioned in the evaporation region, where the one or more second heating sources extend along the first direction from the first sidewall to the second sidewall. The thermal evaporator further includes a linear array of nozzles fluidly coupled with the interior region via the cylindrical wall and operable to deliver the evaporated coating material. The method further includes heating the coating material to be deposited using the one or more first heating sources in the source region to a predetermined temperature to vaporize the coating material to be deposited. The method further includes maintaining the vaporized coating material in vapor form by exposing the vaporized coating material to the one or more second heating sources. The method further includes confining the vaporized coating material in a deposition zone, and moving a continuous flexible substrate through the deposition zone for coating the substrate with the evaporated coating material from the thermal evaporator.

Implementations may include one or more of the following features. The method where the thermal evaporator and deposition zone are positioned in a vacuum chamber for evaporating and depositing the coating material on a substrate in a vacuum environment. The method where the coating material to be evaporated is selected from lithium, sodium, selenium, magnesium, zinc, cadmium, aluminum, gallium, indium, thallium, tin, lead, antimony, bismuth, and tellurium, alkali earth metals, silver, or a combination thereof. The method where the continuous flexible substrate includes a polymer material. The method where the continuous flexible substrate includes a metal.

In another aspect, a non-transitory computer readable medium has stored thereon instructions, which, when executed by a processor, causes the process to perform operations of the above apparatus, method, or both the apparatus and method.

### BRIEF DESCRIPTION OF THE DRAWINGS

So that the manner in which the recited features of the present disclosure can be understood in detail, a more particular description of the aspects, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 illustrates a schematic side view of an evaporation system having one or more cylindrical evaporation assemblies in accordance with one or more implementations of the present disclosure.

FIG. 2A illustrates a schematic perspective view of a cylindrical evaporation assembly in accordance with one or more implementations of the present disclosure.

FIG. 2B illustrates a schematic cross-sectional view of the cylindrical evaporation assembly of FIG. 2A in accordance with one or more implementations of the present disclosure.

FIG. 2C illustrates a schematic side view of the cylindrical evaporation assembly of FIG. 2A in accordance with one or more implementations of the present disclosure.

FIG. 3A illustrates a schematic perspective view of another cylindrical evaporation assembly in accordance with one or more implementations of the present disclosure.

FIG. 3B illustrates a schematic cross-sectional view of the cylindrical evaporation assembly of FIG. 3A in accordance with one or more implementations of the present disclosure.

FIG. 3C illustrates a schematic side view of the cylindrical evaporation assembly of FIG. 3A in accordance with one or more implementations of the present disclosure.

FIG. 4 illustrates a schematic cross-sectional view of yet another cylindrical evaporation assembly in accordance with one or more implementations of the present disclosure.

FIG. 5 illustrates a schematic cross-sectional view of yet another cylindrical evaporation assembly in accordance with one or more implementations of the present disclosure.

FIG. 6A illustrates a schematic perspective view of an evaporation assembly in accordance with one or more implementations of the present disclosure.

FIG. 6B illustrates a schematic cross-sectional view of the evaporation assembly of FIG. 6A in accordance with one or more implementations of the present disclosure.

FIG. 7 illustrates a schematic cross-sectional view of an evaporation system incorporating the cylindrical evaporation assembly of FIG. 5.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Vacuum web coating for anode pre-lithiation and solid metal anode deposition generally involves thick (three to twenty micron) metallic (e.g., lithium) deposition on single-side-coated or double-side-coated flexible substrates, for example, metallic current collectors, such as, copper foil, nickel foil, or metallized plastic web, graphite-coated substrates, or polymer substrates, for example, polyethylene terephthalate (PET) substrates. One technique for deposition is thermal evaporation. Thermal evaporation readily takes place when a source material is heated in an open crucible within a vacuum chamber when a temperature is reached such that there is a sufficient vapor flux from the source for condensation on a cooler substrate. The source material can be heated indirectly by heating the crucible, or directly by a high current electron beam directed into the source material confined by the crucible.

Conventional evaporator systems often involve high temperatures (e.g., approximately 200 to 1500 degrees Celsius) to evaporate, thus placing a high thermal load on the processed web or substrate. Conventional evaporator systems, which use cooling drums also place higher tension on the web (e.g., 200 N to 800 N) to increase contact pressure on the cooling drum. In addition, conventional evaporator systems suffer from high radiative heat load due to the large surface area of the evaporator body at close proximity to the substrate. In addition, conventional evaporator system often use crucibles with external heaters. These external heaters can increase the combined radiative and condensation heat load further increasing thermal load. The increased thermal loads and contact pressures can have several drawbacks. For example, the increased thermal loads and contact pressures can lead to wrinkling of the processed web, tearing of the web during processing, and affect the final product after coating. Further, current evaporator systems are often very sensitive to the inclination angle of deposition, which can present additional challenges when deposition takes place over a cooling drum. In addition, some conventional evaporator systems include complex two body designs, which are very susceptible to leaks in a hot environment thus increasing material costs.

The thermal evaporator described includes a cylindrical evaporator design, which can evaporate material for deposition at high-rates with significantly lower heat loads for evaporation. The cylindrical evaporator design of the present disclosure eliminates the external crucible heater found in currently available evaporator designs. Elimination of the external crucible heater reduces power consumption and decreases the heat load on the web substrate. The cylindrical evaporator design of the present disclosure minimizes heat loss. The cylindrical evaporator design is not sensitive to the inclination angle relative to the substrate. In addition, due to the lower thermal heat load of the cylindrical evaporator design, wrinkling of the web substrate is significantly reduced.

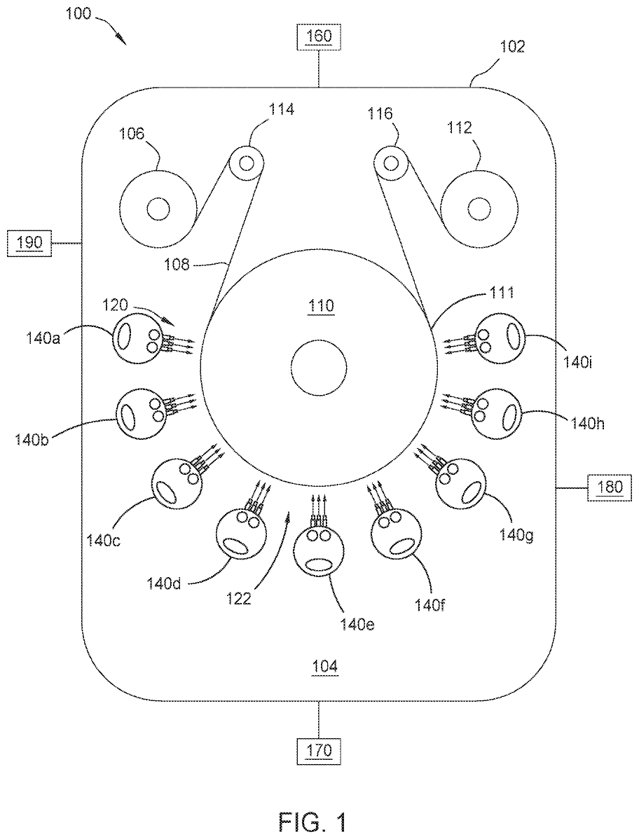

FIG. 1 illustrates a schematic side view of an evaporation system 100 including one or more cylindrical thermal evaporation assemblies 140a-140i (collectively 140), in accordance with one or more implementations of the present disclosure. The evaporation system 100 can be a roll-to-roll system adapted for depositing coatings on web materials, for example, for depositing metal containing film stacks according to the implementations described. In one example, the evaporation system 100 can be used for depositing metals or metal alloys. For example, the evaporation system 100 and the cylindrical thermal evaporation assemblies 140 can be used for depositing metals or metal alloys. Examples of metal and metal alloys include but are not limited to alkali metals (e.g., lithium or sodium), selenium, magnesium, zinc, cadmium, aluminum, gallium, indium, thallium, tin, lead, antimony, bismuth, and tellurium, alkali earth metals, silver, or a combination thereof. These metals or metal alloys can be used for manufacturing energy storage devices, and particularly for film stacks for lithium-containing anode structures. The evaporation system 100 includes a chamber body 102 that defines a common processing environment 104 in which some or all of the processing actions for depositing coatings on web materials can be performed. In one example, the common processing environment 104 is operable as a vacuum environment. In another example, the common processing environment 104 is operable as an inert gas environment. In some examples, the common processing environment 104 can be maintained at a process pressure of 1×10⁻³ mbar or below, for example, 1×10⁻⁴ mbar or below.

The evaporation system 100 is constituted as a roll-to-roll system including an unwinding reel 106 for supplying a continuous flexible substrate 108 or web, a coating drum 110 over which the continuous flexible substrate 108 is processed, and a winding reel 112 for collecting the continuous flexible substrate 108 after processing. The coating drum 110 includes a deposition surface 111 over which the continuous flexible substrate 108 travels while material is deposited onto the continuous flexible substrate 108. The evaporation system 100 can further include one or more auxiliary transfer reels 114, 116 positioned between the unwinding reel 106, the coating drum 110, and the winding reel 112. According to one aspect, at least one of the one or more auxiliary transfer reels 114, 116, the unwinding reel 106, the coating drum 110, and the winding reel 112, can be driven and rotated by a motor. In one example, the motor is a stepper motor. Although the unwinding reel 106, the coating drum 110, and the winding reel 112 are shown as positioned in the common processing environment 104, it should be understood that the unwinding reel 106 and the winding reel 112 can be positioned in separate chambers or modules, for example, at least one of the unwinding reel 106 can be positioned in an unwinding module, the coating drum 110 can be positioned in a processing module, and the winding reel 112 can be positioned in an unwinding module.

The unwinding reel 106, the coating drum 110, and the winding reel 112 can be individually temperature controlled. For example, the unwinding reel 106, the coating drum 110, and the winding reel 112 can be individually heated using an internal heat source positioned within each reel or an external heat source.

In one implementation, which can be combined with other implementations, the one or more cylindrical thermal evaporation assemblies 140 can be removably coupled with the containment shield (not shown). In another implementation, which can be combined with other implementations, the one or more cylindrical thermal evaporation assemblies 140 can be spaced apart from the coating drum 110. The one or more cylindrical thermal evaporation assemblies 140 are positioned to deliver evaporated coating material onto the continuous flexible substrate 108 as the continuous flexible substrate 108 travels through a deposition zone 120 over the deposition surface 111 of the coating drum 110.

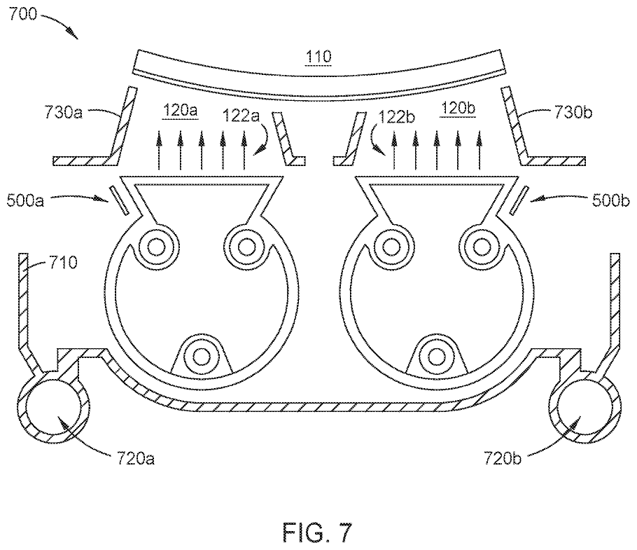

The deposition zone 120 is defined in between the one or more cylindrical thermal evaporation assemblies 140 and the deposition surface 111 of the coating drum 110. In one implementation, which can be combined with other implementations, the deposition zone 120 provides an isolated processing region within the common processing environment 104 of the chamber body 102. The deposition zone 120 can be minimized and defined to conform to a web, for example, the continuous flexible substrate 108 that is wound on a cylindrical cooling drum, for example, the coating drum 110, a planar cooling plate, or in a free span orientation. In one implementation, which can be combined with other implementations, the deposition zone 120 is defined by at least one containment shield (See FIG. 7) disposed between the cylindrical thermal evaporator assembly 140 and the coating drum 110. The containment shield defines the deposition zone 120 for confinement of the evaporated coating material to be deposited.

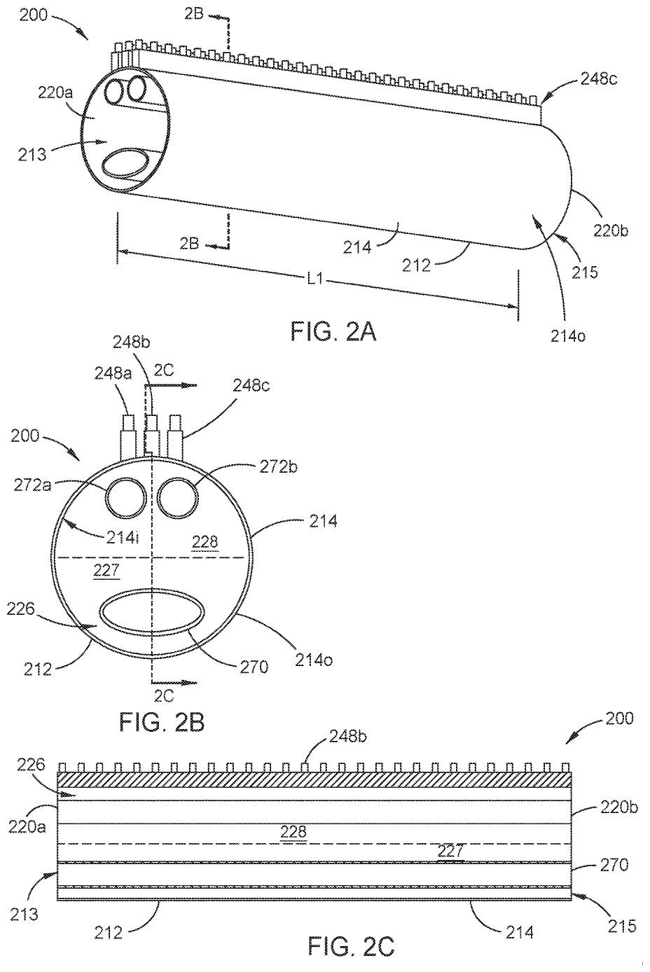

The one or more cylindrical thermal evaporation assemblies 140 will be described in greater detail with reference to FIGS. 2A-7. The one or more cylindrical thermal evaporation assemblies 140 are positioned to perform one or more processing operations to the continuous flexible substrate 108 or web of material. In one example, as depicted in FIG. 1, the one or more cylindrical thermal evaporation assemblies 140 are radially disposed about the coating drum 110. In addition, arrangements other than radial are contemplated. In one implementation, which can be combined with other implementations, the one or more cylindrical thermal evaporation assemblies 140 include a lithium (Li) source. Further, the one or more cylindrical thermal evaporation assemblies 140 can also include a source of an alloy of two or more metals. The coating material to be deposited can be evaporated, for example, by thermal evaporation techniques.

In operation, the one or more cylindrical thermal evaporation assemblies 140 emit a plume of evaporated coating material 122, which is drawn to the continuous flexible substrate 108 where a film of deposited material is formed on the continuous flexible substrate 108.

In addition, although nine cylindrical thermal evaporation assemblies 140a-140i are shown in FIG. 1, it should be understood that any number of evaporation assemblies can be used. In addition, the evaporation system 100 can further include one or more additional deposition sources. For example, the one or more deposition sources as described include an electron beam source and additional sources, which can be selected from the group of CVD sources, PECVD sources, and various PVD sources. Exemplary PVD sources include sputtering sources, electron beam evaporation sources, and thermal evaporation sources. In addition, these additional deposition sources can be positioned radially relative to the deposition surface 111 of the coating drum 110.

In one implementation of the present disclosure, which can be combined with other implementations, the evaporation system 100 is configured to process both sides of the continuous flexible substrate 108. For example, additional evaporation assemblies similar to the one or more cylindrical thermal evaporation assemblies 140 can be positioned to process the opposing side of the continuous flexible substrate 108. Although the evaporation system 100 is configured to process the continuous flexible substrate 108, which is horizontally oriented, the evaporation system 100 can be configured to process substrates positioned in different orientations, for example, the continuous flexible substrate 108 can be vertically oriented. In one implementation of the present disclosure which can be combined with other implementations, the continuous flexible substrate 108 is a flexible polymer substrate, for example, a polyethylene terephthalate “PET” substrate, a flexible conductive substrate, for example a copper foil substrate, or a combination of both. In one implementation of the present disclosure, which can be combined with other implementations, the continuous flexible substrate 108 includes a conductive substrate with one or more layers formed thereon. In one implementation of the present disclosure which can be combined with other implementations, the conductive substrate is a copper substrate.

The evaporation system 100 further includes a gas panel 160. The gas panel 160 uses one or more conduits (not shown) to deliver processing gases to the evaporation system 100. The gas panel 160 can include mass flow controllers and shut-off valves, to control gas pressure and flow rate for each individual gas supplied to the evaporation system 100. Examples of gases that can be delivered by the gas panel 160 include, but are not limited to, inert gases for pressure control (e.g., argon), etching chemistries including but not limited to diketones used for in-situ cleaning of the evaporation system 100, and deposition chemistries including but not limited to 1,1,1,2-Tetrafluoroethane or other hydrofluorocarbons and trimethylaluminum, titanium tetrachloride, or other metal organic precursors used for in-situ tens of nanometer thick reactive lithium mixed conductor surface modification.

The evaporation system 100 further includes a system controller 170 operable to control various aspects of the evaporation system 100. The system controller 170 facilitates the control and automation of the evaporation system 100 and can include a central processing unit (CPU), memory, and support circuits (or I/O). Software instructions and data can be coded and stored within the memory for instructing the CPU. The system controller 170 can communicate with one or more of the components of evaporation system 100 via, for example, a system bus. A program (or computer instructions) readable by the system controller 170 determines which tasks are performable on a substrate. In some aspects, the program is software readable by the system controller 170, which can include code for monitoring chamber conditions, including independent temperature control of the one or more cylindrical thermal evaporation assemblies 140. Although only a single system controller, the system controller 170 is shown, it should be appreciated that multiple system controllers can be used with the aspects described.

The evaporation system 100 may further include a power supply 180 for supplying power to the components of the evaporation system 100. For example, the power supply 180 may be electrically coupled with the one or more heating sources in the cylindrical thermal evaporator assemblies 140.

The evaporation system 100 may further include a coating material supply source 190 for supplying coating material to each of the cylindrical thermal evaporator assemblies. In one implementation, which can be combined with other implementations, the coating material supply maintains the coating material in liquid form.

In one example, each cylindrical thermal evaporator assembly 140a-i is spaced from an adjacent cylindrical thermal evaporator assembly by about 22 to about 26 centimeters, the coating drum 110 is a gas cushion drum, which is cooled in a range from about −10 degrees Celsius to about 50 degrees Celsius, and a travel speed of the continuous flexible substrate is approximately 2 meters/minute, which provides a line speed cooling time between the nozzles of adjacent cylindrical thermal evaporator assemblies 140a-i of about 12 to 13 seconds.

FIG. 2A illustrates a schematic perspective view of a cylindrical evaporation assembly 200 in accordance with one or more implementations of the present disclosure. FIG. 2B illustrates a schematic cross-sectional view of the cylindrical evaporation assembly 200 of FIG. 2A in accordance with one or more implementations of the present disclosure. FIG. 2C illustrates a schematic side view of the cylindrical evaporation assembly 200 of FIG. 2A in accordance with one or more implementations of the present disclosure. The cylindrical evaporation assembly 200 can be used in place of the cylindrical thermal evaporation assembly 140 depicted in FIG. 1.

The cylindrical evaporation assembly 200 is designed to hold and evaporate a coating material to be evaporated, for example, a metal or metal alloy. The cylindrical evaporation assembly 200 includes an evaporator body 212 for holding and evaporating a coating material to be deposited. The cylindrical evaporation assembly 200 further includes one or more linear arrays of nozzles 248a-c fluidly coupled with the evaporator body 212 and operable to deliver the evaporated coating material. The linear array of nozzles 248a-c is responsible for evaporation rate. The higher the number of nozzles, the higher the evaporation rate over a certain surface area of the evaporator. Although the evaporator body 212 is shown as a cylindrical or cylindrical body, other suitable shapes for the evaporator body 212 are also contemplated. Referring to FIG. 2A, the evaporator body 212 includes a cylindrical wall 214 that has a first end 213 and a second end 215 opposite the first end 213. The cylindrical wall 214 further includes an inner surface 214i and an outer surface 2140.

The evaporator body 212 further includes a first sidewall 220a and a second sidewall 220b opposite the first sidewall 220a (collectively 220) extending upward from and perpendicular to the cylindrical wall 214. The first sidewall 220a is perpendicular to and coupled with the first end 213 of the cylindrical wall 214. The distance between the first sidewall 220a and the second sidewall 220b opposite the first sidewall 220a define a length dimension “L1” of the evaporator body 212. The length dimension “L1” may be determined by the width of the substrate that is processed. In one example, the length dimension “L1” is 1 meter or less, for example, in a range from about 0.5 meters to about 1 meter. The first sidewall 220a and the second sidewall 220b each define a circumference of the evaporator body 212. Referring to FIG. 2B, the pair of opposing sidewalls 220a-b and the cylindrical wall 214 define an interior region 226 for holding the material to be evaporated. The interior region 226 includes a source region 227 and an evaporation region 228. The source region 227 is operable for holding the coating material to be evaporated/deposited in a molten and/or liquid form and heating the coating material to evaporate the coating material for deposition. In at least one implementation, the source region 227 is sized to hold from about 0.5 liters of lithium to about 20 liters of lithium. In one example, a maximum surface area is achieved when the source region is filled at 50% by volume and the surface area variation to dead volume is approximately 10%. The coating material to be evaporated/deposited can be supplied to the source region 227 of the evaporator body 212 from an external source, for example, the coating material supply source 190. The evaporation region 228 is heated to maintain the evaporated coating material in vapor phase for deposition.

The interior region 226 further includes one or more heating sources. The source region 227 includes one or more heating sources 270. Although a single heating source 270 is shown in the source region 227 of FIG. 2B, any number of heating sources may be used to maintain/heat the coating material to a predetermined temperature for evaporation. The heating source 270 is used to heat and evaporate the coating material to be evaporated. The heating source 270 may be submerged or partially submerged in the coating material to be evaporated. In one implementation, which can be combined with other implementations, the heating source 270 is a cylindrical heater, for example, a heating rod. In one implementation, which can be combined with other implementations, the heating source includes a graphite heater enclosed inside a stainless steel tube. When current passes through the graphite heater, it radiates heat to the tube submerged inside the material to be evaporated. As shown in FIG. 2C, the heating source 270 may extend along a first direction from the first sidewall 220a to the second sidewall 220b of the evaporator body 212. The first direction may be parallel to the inner surface 214i of the cylindrical wall 214.

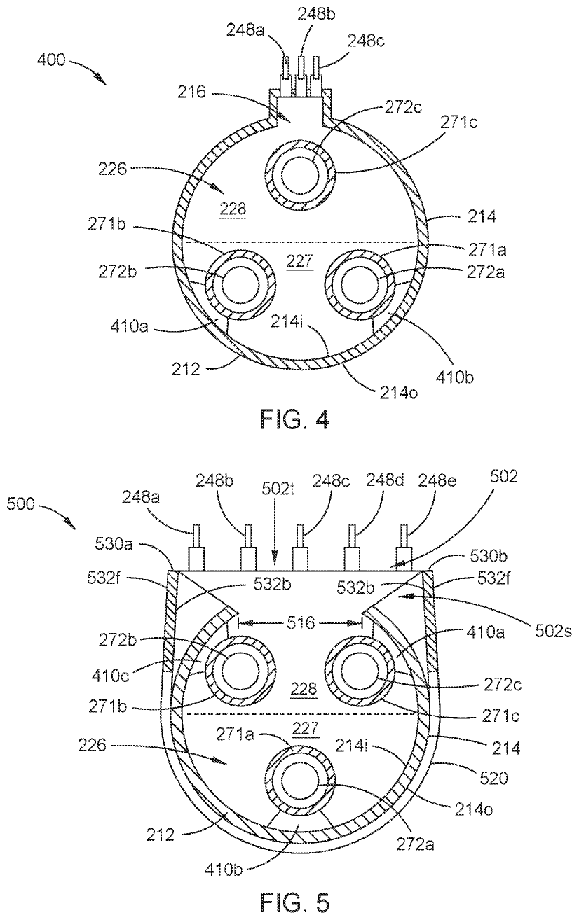

The evaporation region 228 further includes one or more heating sources 272a, 272b for maintaining the evaporated coating material from the source region 227 in an evaporated state. Although two heating sources 272a-b are shown in the evaporation region 228 of FIG. 2B, any number of heating sources may be used to maintain/heat the evaporated coating material to a predetermined temperature. The heating source 270 is used for maintaining the evaporated coating material from the source region 227 in an evaporated state. As shown in FIG. 2C, the heating sources 272a-b may be positioned adjacent to the nozzles 248. In one implementation, which can be combined with other implementations, the heating sources 272a-b are cylindrical heaters, for example, heating rods. As shown in FIG. 2B, the heating sources 272a-b may extend along the first direction from the first sidewall 220a to the second sidewall 220b of the evaporator body 212. The one or more heating sources 270, 272 may comprises any suitable material. In one implementation, which can be combined with other implementations, the one or more heating sources 270, 272 comprises a material selected from graphite, aluminum oxide, aluminum nitride, boron nitride, silicon carbide, and titanium diboride. In particular implementations, the one or more heating sources 270, 272 comprises graphite. The one or more heating sources 270, 272 are electrically coupled with a power supply, for example, the power supply 180, for providing an electrical current therethrough for heating the one or more heating sources 270, 272. The one or more heating sources 270, 272 may be positioned in a corresponding tube as will be described with respect to FIG. 4 and FIG. 5.

The evaporator body 212 may comprise any suitable material having high thermal conductivity. In one implementation, which can be combined with other implementations, the evaporator body 212 comprises a material selected from molybdenum, graphite, stainless steel, boron nitride, titanium, or a combination thereof. Pyrolytic boron nitride is generally inert, can withstand high temperatures, is generally clean and does not contribute undesirable impurities to the vacuum environment, is generally transparent to certain wavelengths of infrared radiation, and can be fabricated into complex shapes, for example.

In one implementation, which can be combined with other implementations, the evaporator body 212 is machined from a single piece of material. In another implementation, which can be combined with other implementations, the first sidewall 220a and the second sidewall 220b are attached to the cylindrical wall 214. Any suitable attachment techniques can be used to attach the sidewalls 220a-b to the cylindrical wall 214. For example, the sidewalls 220a-b can be welded to the cylindrical wall 214. The sidewalls 220a-b can be bolted to the cylindrical wall 214.

The cylindrical evaporation assembly 200 further includes the linear array of nozzles 248a-248c (collectively 248) in fluid communication with the interior region 226. In one implementation, which can be combined with other implementations, the linear array of nozzles 248 is aligned with an opening 216 defined by the cylindrical wall 214. In one implementation, which can be combined with other implementations, the linear array of nozzles 248 is positioned adjacent to or on the cylindrical wall 214. In one implementation, which can be combined with other implementations, the linear array of nozzles 248 extend along the first direction from the first sidewall 220a to the second sidewall 220b of the evaporator body 212.

One or more nozzles of the linear array of nozzles 248 deliver evaporated coating material from the interior region 226 toward the flexible continuous substrate where the evaporated coating material is deposited. One or more nozzles of the linear array of nozzles 248 includes an opening defined by a diameter. The opening of the nozzles can be any diameter sufficient to deliver the evaporated coating material at targeted vapor pressures. In one implementation, which can be combined with other implementations, one or more nozzles or the linear array of nozzles 248 has an opening defined by a diameter in a range from about 1 millimeter to about 10 millimeters, or in a range from about 1.2 millimeters to about 5 millimeters, or in a range from about 4 millimeters to about 4.5 millimeters.

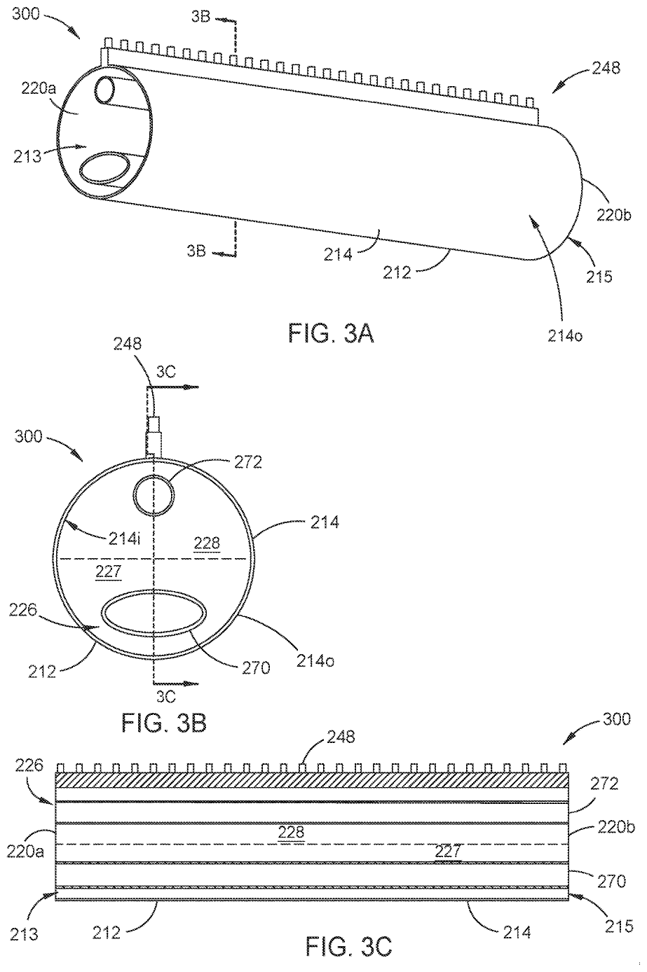

FIG. 3A illustrates a schematic perspective view of another cylindrical evaporation assembly 300 in accordance with one or more implementations of the present disclosure. FIG. 3B illustrates a schematic cross-sectional view of the cylindrical evaporation assembly 300 of FIG. 3A in accordance with one or more implementations of the present disclosure. FIG. 3C illustrates a schematic side view of the cylindrical evaporation assembly 300 of FIG. 3A in accordance with one or more implementations of the present disclosure. The cylindrical evaporation assembly 300 can be used in place of the cylindrical thermal evaporation assembly 140 depicted in FIG. 1.

The cylindrical evaporation assembly 300 is similar to the cylindrical evaporation assembly 200 depicted in FIGS. 2A-2C, except that the cylindrical evaporation assembly 300 includes one linear array of nozzles 248 and one heating source 272 positioned in the evaporation region 228.

FIG. 4 illustrates a schematic cross-sectional view of yet another cylindrical evaporation assembly 400 in accordance with one or more implementations of the present disclosure. The cylindrical evaporation assembly 400 can be used in place of the cylindrical thermal evaporation assembly 140 depicted in FIG. 1. The cylindrical evaporation assembly 400 includes the plurality of heating sources 272a-c. The plurality of heating sources 272a-c may be positioned in a corresponding tube 271a-c. The tube 271a-c may be composed of a thermally conductive material, for example, stainless steel. The heating sources 272a-b are positioned in the source region 227 and the heating source 272c is positioned in the evaporation region 228. In one implementation, which can be combined with other implementations, the heating sources 272a-b positioned in the source region 227 are conductively coupled with the evaporator body 212 and thus conductively heat the evaporator body 212. In one implementation, which can be combined with other implementations, the heating sources 272a-b may be conductively coupled with the evaporator body 212 via heating source mounts 410a-b as depicted in FIG. 4. The heating source mounts 410a-b may be composed of any suitable thermally conductive material. In one implementation, which can be combined with other implementations, the heating source mounts 410a-b may be composed of the same material as the evaporator body 212 and/or the tubes 271a-c. In another implementation, the heating source mounts 410a-b are composed of a thermally conductive material different from the thermally conductive material of the evaporator body 212. The heating source 272c positioned in the evaporation region provides radiative heat. In one implementation, which can be combined with other implementations, as depicted in FIG. 4, the heating source 272c is not conductively coupled with the evaporator body 212. The combination of radiative heat from the heating source 272c and conductive heat from the heating sources 272a-b help provide uniform heating to the inner surface 214i or evaporative surface of the evaporator body 212, which helps reduce cooling of the inner surface 214i. If the inner surface 214i is allowed to cool this can adversely affect the evaporation rate of the coating material.

FIG. 5 illustrates a schematic cross-sectional view of yet another cylindrical evaporation assembly 500 in accordance with one or more implementations of the present disclosure. The cylindrical evaporation assembly 500 can be used in place of the cylindrical thermal evaporation assembly 140 depicted in FIG. 1. The evaporator body 212 defines an opening 516 through which the evaporated coating material travels into a nozzle assembly body 502. The opening 516 defines the surface area of evaporation. The cylindrical wall 214 defines the opening 516, which has a first width “W1”. The opening 516 provides a surface area for evaporation.

The cylindrical evaporation assembly 500 further includes the nozzle assembly body 502 positioned along the cylindrical wall 214. In one implementation, which can be combined with other implementations, the nozzle assembly body 502 has an opening, which is aligned with the opening 516 defined by the cylindrical wall 214. In one implementation, which can be combined with other implementations, the nozzle assembly body 502 is positioned adjacent to or on the cylindrical wall 214. In one implementation, which can be combined with other implementations, the nozzle assembly body 502 has sidewalls 502s, which expand outward from the opening 516 having width “W1” to a top surface 502t of the nozzle assembly body 502 having a width “W2”. In one implementation, which can be combined with other implementations, the nozzle assembly body 502 has a conical-type shape. Any suitable shapes for the nozzle assembly body may be used. This increase in surface area helps reduce condensation heat load per unit area.

The nozzle assembly body 502 is fluidly coupled with the linear array of nozzles 248a-248e (collectively 248). The cylindrical evaporation assembly 500 further includes the plurality of heating sources 272a-c. The heating source 272a is positioned in the source region 227 and the heating sources 272b and 272c are positioned in the evaporation region 228. The heating sources 272a-c are conductively coupled with the evaporator body 212 and thus conductively heat the evaporator body 212. In one implementation, which can be combined with other implementations, the heating sources 272a-c may be conductively coupled with the evaporator body 212 via heating source mounts 410a-c as depicted in FIG. 5.

In one implementation, which can be combined with other implementations, the cylindrical evaporation assembly 500 further includes an insulating material 520. The insulating material 520 surrounds at least a portion of the evaporator body 212. For example, as depicted in FIG. 5, the insulating material 520 covers portions of the cylindrical wall 214 and the first sidewall 220a and the second sidewall 220b. The insulating material 520 reduces the emission of radiative heat from the evaporator body 212. Any suitable insulating material 520 may be used. Examples of the insulating material 520 include but are not limited to polyether ether ketone (PEEK).

In one implementation, which can be combined with other implementations, the cylindrical evaporation assembly 500 further includes one or more reflectors 530a-b (collectively 530) as depicted in FIG. 5. The reflectors 530a-b reduce radiative heat loss from the evaporator body 212. The reflectors 530a-b reflect back most of the energy depending of the emissivity and the reflectivity of the material. The reflectors 530a-b include a backside surface 532b, which faces the evaporator body 212, and an opposing frontside surface 532f, which faces the continuous flexible substrate 108. At least one of the backside surface 532b and the frontside surface 532f is highly polished to a mirror-like finish to maximize the heat shielding function of the reflectors 530a-b. In one implementation, which can be combined with other implementations, the backside surface 532b of the reflectors 530a-b within line of sight of the evaporator body 212 are highly polished to a mirror-like finish. In one implementation, the reflectors 530a-b are formed from stainless steel and are first machined to a smoothness of, for example, 34 Ra. The backside surface 532b and the frontside surface 532f are then mechanically polished to an increased smoothness of, for example, 8 Ra. Finally, these surfaces are electropolished and chemically polished to a further increased smoothness of 2 Ra so that the reflectors 530a-b have a very shiny, mirror-like finish. Although the reflectors 530a-b have been described as being formed from a stainless steel material, it is recognized that other materials may be used. In general, it is preferred that highly reflective, low emissivity metals be utilized including aluminum, gold, and silver. These highly reflective metals can be coated onto a reflector formed of a different metal.

The reflectors 530a-b include or are formed from metal, for example, copper. The reflectors 530a-b can be polished. In some implementations, which can be combined with other implementations, the backside surface 532b of the reflectors 530a-b is polished. It has been found by the inventors that polishing the one or more reflectors 530a-b on the backside surface 532b can minimize radiative heat loss from the evaporator body 212 and thus reduce the heat load on the web substrate. As the reflectors 530a-b are heated, the emissivity of the part typically changes. It has been found by the inventors that exposing the reflectors to a mechanical polish followed by an electro-polish reduces the emissivity of the reflectors 530a-b.

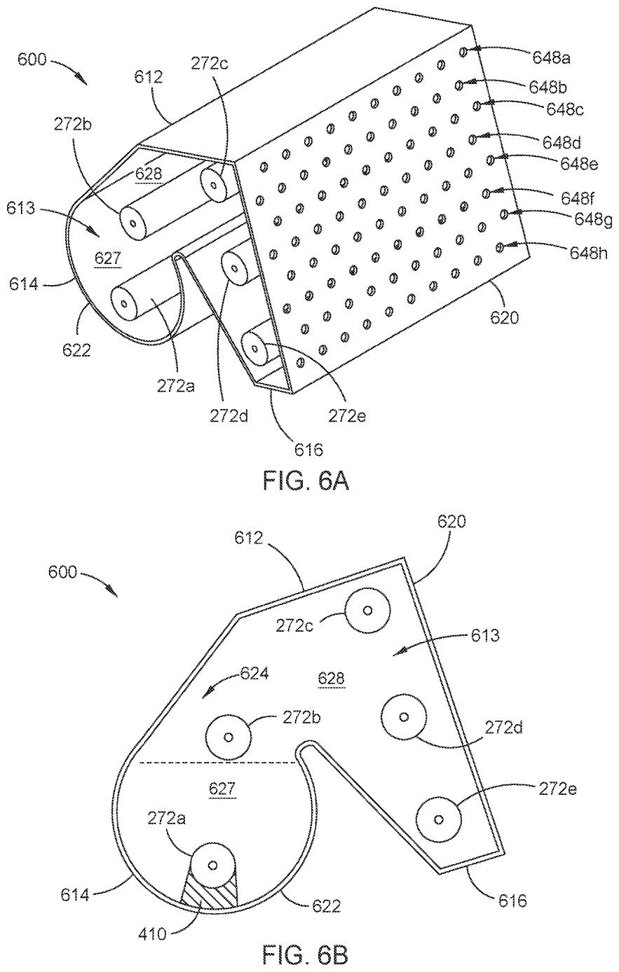

FIG. 6A illustrates a partial perspective view of an evaporation assembly 600 in accordance with one or more implementations of the present disclosure. FIG. 6B illustrates a schematic cross-sectional view of the evaporation assembly 600 of FIG. 6A in accordance with one or more implementations of the present disclosure. The evaporation assembly 600 can be used in place of the cylindrical thermal evaporation assembly 140 depicted in FIG. 1. It is particularly beneficial to use the evaporation assembly 600 in implementations where the evaporation assembly 600 is tilted, for example, where the evaporation assembly 600 is positioned around the coating drum 110 shown in FIG. 1.

The evaporation assembly 600 is designed to hold and evaporate a coating material to be evaporated, for example, a metal or metal alloy. The evaporation assembly 600 includes an evaporator body 612 for holding and evaporating a coating material to be deposited. The evaporator body 612 defines an interior region 613. In at least one implementation, which can be combined with other implementations, the interior region defines a surface area in a range from about 18,500 mm² to about 42840 mm². The evaporator body 612 includes a cylindrical portion 614 and an evaporator portion 616. The evaporator portion 616 includes a nozzle plate 620. The nozzle plate 620 includes a plurality of nozzles 648 fluidly coupled with the interior region 613 and operable to deliver the evaporated coating material. Although the cylindrical portion 614 is shown as a cylindrical body, other suitable shapes for the cylindrical portion 614 are also contemplated. The cylindrical portion 614 includes a cylindrical wall 622 that defines an opening 624 through which the evaporated coating material can travel into the evaporator portion 616 of the evaporator body 612. The evaporator body 612 further includes a first sidewall (not shown) and a second sidewall (not shown) opposite the first sidewall. Referring to FIG. 6A, the pair of opposing sidewalls, the cylindrical portion 614, and the evaporator portion 616 define an interior region 613 for holding the material to be evaporated. The interior region 613 includes a source region 627 and an evaporation region 628. The source region 627 is operable for holding a material to be evaporated/deposited in a molten and/or liquid form and heating the material to evaporate the material. The material to be evaporated/deposited can be supplied to the source region 627 of the evaporator body 612 from an external source. The evaporation region 628 is heated to maintain the evaporated source material in vapor phase.

The interior region 613 further includes one or more heating sources. The source region 627 includes one or more heating sources 272a. Although a single heating source 272a is shown in the source region 627 of FIGS. 6B-6B, any number of heating sources may be used to maintain/heat the source material to a targeted temperature. The heating source 272a is used to heat and evaporate the coating material to be deposited. The heating source 272a may be submerged or partially submerged in the material to be evaporated. In one implementation, which can be combined with other implementations, the heating source 272a is a cylindrical heater, for example, a heating rod. The heating source 272a may extend from the first sidewall to the second sidewall of the evaporator body 612. In one implementation, which can be combined with other implementations, the heating source 272a is coupled with the evaporator body 612 via the heating source mount 410. The heating source mount 410 may be composed of any suitable thermally conductive material. In some implementations, the heating source mounts 410 may be composed of the same material as the evaporator body 612. In other implementations, the heating source mount 410 is composed of a thermally conductive material different from the thermally conductive material of the evaporator body 612.

The interior region 613 may include any number of heating sources 272a-e (collectively 272). The evaporation region 628 further includes one or more heating sources 272b-e for maintaining the evaporated coating material from the source region 227 in an evaporated state. Although four heating sources 272b-e are shown in the evaporation region 628, any number of heating sources may be used to maintain/heat the source material to a targeted temperature. The heating sources 272b-e are used for maintaining the evaporated coating material from the source region 627 in an evaporated state. As shown in FIG. 6B, the heating sources 272c-e may be positioned adjacent to the nozzle plate 620. In one implementation, which can be combined with other implementations, the heating sources 272a-e are cylindrical heaters, for example, heating rods. The heating sources 272a-e may extend from the first sidewall to the second sidewall of the evaporator body 612.

The evaporator body 612 can be formed of a material having high-thermal conductivity, such as molybdenum, graphite, stainless steel, or boron nitride. In one example, the evaporator body 612 is composed of pyrolytic boron nitride.

In one implementation, which can be combined with other implementations, the evaporator body 612 is machined from a single piece of material. In another implementation, which can be combined with other implementations, the evaporator body 612 is formed from multiple pieces, which are attached together. Any suitable attachment techniques can be used to attach the multiple pieces together. For example, the nozzle plate 620 can be welded or bolted to the remainder of the evaporator body 612. The sidewalls 220a-b can be bolted to the cylindrical wall 214. For example, the nozzle plate 620 may be welded to the remainder of the evaporator body 612.

The evaporation assembly 600 further includes a linear array of nozzles 648a-648h (collectively 648) positioned along the nozzle plate 620. One or more nozzles of the linear array of nozzles 648 deliver evaporated coating material from the interior region 613 toward the web where the evaporated coating material is deposited. One or more nozzles of the linear array of nozzles 648 includes an opening defined by a diameter. The opening of the nozzles can be any diameter sufficient to deliver the evaporated coating material at targeted vapor pressures. In one implementation, which can be combined with other implementations, one or more nozzles or the linear array of nozzles 648 has an opening defined by a diameter from about 1.2 millimeters to about 5 millimeters, for example, from about 4 millimeters to about 4.5 millimeters.

FIG. 7 illustrates a schematic cross-sectional view of an evaporation system 700 incorporating the cylindrical evaporation assembly of FIG. 5. The evaporation system 700 includes a frame 710 for holding one or more cylindrical evaporator assemblies. In one implementation, which can be combined with other implementations, the frame 710 holds a pair cylindrical evaporation assemblies 500a, 500b (collectively 500). In one implementation, which can be combined with other implementations, the frame 710 defines one or more cooling channels 720a, 720b for accommodating a cooling fluid to cool the frame 710 and the cylindrical evaporator assemblies 500a, 500b. In one implementation, which can be combined with other implementations, the evaporation system 700 further includes one or more containment shields 730a, 730b (collectively 730). The containment shields 730 may be part of the frame 710 or may be separate from the frame 710. The number of containment shields 730 typically corresponds to the number of cylindrical evaporator assemblies 500 positioned in the frame 710. A deposition zone 120a, 120b (collectively 120) is defined by the containment shield 730 disposed between the cylindrical thermal evaporator assemblies and the coating drum 110. The containment shield 730 defines the deposition zone 120 for confinement of the plume of evaporated coating material 122a, 122b (collectively 122) to be deposited. In one implementation, which can be combined with other implementations the containment shield 730 is heated to re-evaporate lithium from the surface of the one or more containment shields 730a-b.

In operation, a method of evaporating a coating material for coating a continuous flexible substrate if provided. The method includes supplying a quantity of a coating material to be evaporated into a source region of a thermal evaporator. The thermal evaporator includes an evaporator body operable for holding and evaporating the coating material to be deposited. The evaporator body includes a cylindrical wall having a first end and a second end opposite the first end; a first sidewall perpendicular to and coupled with the first end of the cylindrical wall; a second sidewall perpendicular to and coupled with the second end of the cylindrical wall. The cylindrical wall, the first sidewall, and the second sidewall define an interior region. The interior region has the source region operable for holding and evaporating the coating material to be deposited and an evaporation region, which is heated to maintain the evaporated coating material to be deposited in vapor phase. The thermal evaporator further includes one or more first heating sources positioned in the source region, where the one or more first heating sources extend along a first direction from the first sidewall to the second sidewall; one or more second heating sources positioned in the evaporation region, where the one or more second heating sources extend along the first direction from the first sidewall to the second sidewall. The thermal evaporator further includes a linear array of nozzles fluidly coupled with the interior region via the cylindrical wall and operable to deliver the evaporated coating material. The method further includes heating the coating material to be deposited using the one or more first heating sources in the source region to a predetermined temperature to vaporize the coating material to be deposited. The method further includes maintaining the vaporized coating material in vapor form by exposing the vaporized coating material to the one or more second heating sources. The method further includes confining the vaporized coating material in a deposition zone, and moving a continuous flexible substrate through the deposition zone for coating the substrate with the evaporated coating material from the thermal evaporator. The method where the thermal evaporator and deposition zone are positioned in a vacuum chamber for evaporating and depositing the coating material on a substrate in a vacuum environment. The method where the coating material to be evaporated is selected from lithium, sodium, selenium, magnesium, zinc, cadmium, aluminum, gallium, indium, thallium, tin, lead, antimony, bismuth, and tellurium, alkali earth metals, silver, or a combination thereof. The method where the continuous flexible substrate includes a polymer material. The method where the continuous flexible substrate includes a metal.

Implementations can include one or more of the following potential advantages. The thermal evaporator described includes a cylindrical evaporator design, which enables a high-rate of evaporation with significantly lower heat loads on the web substrate. The cylindrical evaporator design of the present disclosure eliminates the external crucible heater found in currently available evaporator designs. Elimination of the external crucible heater reduces power consumption and decreases the heat load on the web substrate. The high-rate cylindrical evaporator design of the present disclosure minimizes heat loss. The high-rate cylindrical evaporator design is not sensitive to the inclination angle relative to the substrate. In addition, due to the lower thermal heat load of the cylindrical evaporator design, wrinkling of the web substrate is significantly reduced. The thermal evaporator design described is capable of using alkali metals and metal alloys at very high uniform evaporation rates at relatively low temperatures. The thermal evaporator design described enables roll-to-roll processes to be run with thin metal substrates at substantially lower tension and higher web speed. This lower tension helps reduce wrinkling of thin metal substrates as it helps retain the tensile strength of the thin metal substrate. Due to the lower thermal budget of evaporation, substrate cooling requirements are also minimized. The lower thermal budget of evaporation also enables ramp up and ramp down of evaporators quickly, which increases the production tool yield.

In the Summary and in the Detailed Description, and the Claims, and in the accompanying drawings, reference is made to particular features (including method steps) of the present disclosure. It is to be understood that the disclosure in this specification includes all possible combinations of such particular features. For example, where a particular feature is disclosed in the context of a particular aspect or implementation of the present disclosure, or a particular claim, that feature can also be used, to the extent possible in combination with and/or in the context of other particular aspects and implementations of the present disclosure, and in the present disclosure generally.

The term “comprises” and grammatical equivalents thereof are used to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components.

Where reference is made to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

According to some implementations, evaporation processes and evaporation apparatus for layer deposition on substrates, for example on flexible substrates, are provided. Thus, flexible substrates can be considered to include among other things films, foils, webs, strips of plastic material, metal, or other materials. Typically, the terms “web,” “foil,” “strip,” “substrate” and the like are used synonymously. According to some implementations, components for evaporation processes, apparatuses for evaporation processes and evaporation processes according to implementations described can be provided for the above-described flexible substrates. However, they can also be provided in conjunction with non-flexible substrates such as glass substrates or the like, which are subject to the reactive deposition process from evaporation sources.

Implementations and all of the functional operations described in this specification can be implemented in digital electronic circuitry, or in computer software, firmware, or hardware, including the structural means disclosed in this specification and structural equivalents thereof, or in combinations of them. Implementations described can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the disclosure may be devised without departing from the basic scope thereof, and the scope thereof is determined by the claims that follow.

1. A thermal evaporator, comprising:
an evaporator body operable for holding and evaporating a coating material to be deposited, the evaporator body, comprising:
a cylindrical wall having a first end and a second end opposite the first end;
a first sidewall perpendicular to and coupled with the first end of the cylindrical wall;
a second sidewall perpendicular to and coupled with the second end of the cylindrical wall, wherein the cylindrical wall, the first sidewall, and the second sidewall define an interior region, the interior region having a source region operable for holding and evaporating the coating material to be deposited and an evaporation region, which is operable for heating to maintain the evaporated coating material to be deposited in vapor phase;
one or more first heating sources positioned in the source region, wherein the one or more first heating sources extend along a first direction from the first sidewall to the second sidewall;
one or more second heating sources positioned in the evaporation region, wherein the one or more second heating sources extend along the first direction from the first sidewall to the second sidewall; and
a linear array of nozzles fluidly coupled with the interior region via the cylindrical wall and operable to deliver the evaporated coating material.

2. The thermal evaporator of claim 1, wherein the evaporator body comprises a material selected from molybdenum, graphite, stainless steel, boron nitride, or a combination thereof.

3. The thermal evaporator of claim 1, wherein at least one of the one or more first heating sources and the one or more second heating sources comprise a heating rod.

4. The thermal evaporator of claim 3, wherein the heating rod is positioned in a tube that extends along the first direction from the first end of the cylindrical wall to the second end of the cylindrical wall, the tube comprising a thermally conductive material.

5. The thermal evaporator of claim 4, wherein the one or more second heating sources are conductively coupled with the evaporator body via a source mount and the source mount comprises the same material as the evaporator body.

6. The thermal evaporator of claim 3, wherein the one or more second heating sources are positioned adjacent to the linear array of nozzles.

7. The thermal evaporator of claim 1, wherein the linear array of nozzles extends along the first direction from the first sidewall to the second sidewall.

8. The thermal evaporator of claim 1, wherein at least one of the one or more first heating sources and the one or more second heating sources comprises a material selected from graphite, aluminum oxide, aluminum nitride, boron nitride, and titanium diboride.

9. A system for coating a substrate by evaporating a coating material in a vacuum chamber, the system comprising:
a thermal evaporator, comprising:
an evaporator body operable for holding and evaporating a coating material to be deposited, the evaporator body, comprising:
a cylindrical wall having a first end and a second end opposite the first end;
a first sidewall perpendicular to and coupled with the first end of the cylindrical wall;
a second sidewall perpendicular to and coupled with the second end of the cylindrical wall, wherein the cylindrical wall, the first sidewall, and the second sidewall define an interior region, the interior region having a source region operable for holding and evaporating the coating material to be deposited and an evaporation region, which is operable for heating to maintain the evaporated coating material to be deposited in vapor phase;
one or more first heating sources positioned in the source region, wherein the one or more first heating sources extend along a first direction from the first sidewall to the second sidewall;
one or more second heating sources positioned in the evaporation region, wherein the one or more second heating sources extend along the first direction from the first sidewall to the second sidewall; and
a linear array of nozzles fluidly coupled with the interior region via the cylindrical wall and operable to deliver the evaporated coating material;
at least one containment shield disposed about the thermal evaporator, the containment shield defining a deposition zone for confinement of the evaporated coating material to be deposited;
a coating drum for supporting a continuous flexible substrate to be coated in the deposition zone; and
a vacuum chamber, wherein the thermal evaporator, the at least one containment shield, and the coating drum are disposed therein.

10. The system of claim 9, wherein the evaporator body comprises a material selected from molybdenum, graphite, stainless steel, boron nitride, or a combination thereof.

11. The system of claim 9, wherein at least one of the one or more first heating sources and the one or more second heating sources comprise a heating rod.

12. The system of claim 11, wherein the heating rod is positioned in a tube that extends along the first direction from the first end of the cylindrical wall to the second end of the cylindrical wall, the tube comprising a thermally conductive material.

13. The system of claim 12, wherein the one or more second heating sources are conductively coupled with the evaporator body via a source mount and the source mount comprises the same material as the evaporator body.

14. The system of claim 11, wherein the one or more second heating sources are positioned adjacent to the linear array of nozzles.

15. The system of claim 9, wherein the linear array of nozzles extends along the first direction from the first sidewall to the second sidewall.

16. A method of evaporating a coating material for coating a continuous flexible substrate, the method comprising:
supplying a quantity of a coating material to be evaporated into a source region of a thermal evaporator, the thermal evaporator comprising:
an evaporator body operable for holding and evaporating the coating material to be deposited, the evaporator body, comprising:
a cylindrical wall having a first end and a second end opposite the first end;
a first sidewall perpendicular to and coupled with the first end of the cylindrical wall;
a second sidewall perpendicular to and coupled with the second end of the cylindrical wall, wherein the cylindrical wall, the first sidewall, and the second sidewall define an interior region, the interior region having the source region operable for holding and evaporating the coating material to be deposited and an evaporation region, which is operable for heating to maintain the evaporated coating material to be deposited in vapor phase;
one or more first heating sources positioned in the source region, wherein the one or more first heating sources extend along a first direction from the first sidewall to the second sidewall;
one or more second heating sources positioned in the evaporation region, wherein the one or more second heating sources extend along the first direction from the first sidewall to the second sidewall; and
a linear array of nozzles fluidly coupled with the interior region via the cylindrical wall and operable to deliver the evaporated coating material.
heating the coating material to be deposited using the one or more first heating sources in the source region to a predetermined temperature to vaporize the coating material to be deposited;
maintaining the vaporized coating material in vapor form by exposing the vaporized coating material to the one or more second heating sources;
confining the vaporized coating material in a deposition zone; and
moving a continuous flexible substrate through the deposition zone for coating the substrate with the evaporated coating material from the thermal evaporator.

17. The method of claim 16, wherein the thermal evaporator and deposition zone are positioned in a vacuum chamber for evaporating and depositing the coating material on a substrate in a vacuum environment.

18. The method of claim 17, wherein the coating material to be evaporated is selected from lithium, sodium, selenium, magnesium, zinc, cadmium, aluminum, gallium, indium, thallium, tin, lead, antimony, bismuth, and tellurium, alkali earth metals, silver, or a combination thereof.

19. The method of claim 18, wherein the continuous flexible substrate comprises a polymer material.

20. The method of claim 18, wherein the continuous flexible substrate comprises a metal.
